(19) United States
(12) Patent Application Publication
(10) Pub. No.: US 2007/0195382 A1
(43) Pub. Date: Aug. 23, 2007

(54) Apparatus for gamut mapping and method of generating gamut boundary using the same

(75) Inventors: Min-ki Cho, Seoul (KR); Byoung-ho Kang, Yongin-si (KR); Heui-keun Choh, Seongnam-si (KR); Ronnier Luo, Leeds (GB)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/604,803

(22) Filed: Nov. 28, 2006

(30) Foreign Application Priority Data
Feb. 17, 2006 (KR) 10-2006-0015716

(51) Int. Cl. G03F 3/08

(52) U.S. Cl. 358/518

(57) ABSTRACT

A gamut-mapping apparatus includes a color-coordinate-conversion module which converts color coordinate values of an inputted color sample to values of a spherical coordinate system, and which divides the spherical coordinate system into a predetermined number of segments; a judgment module which detects color coordinate values having a largest radius among color coordinate values included in the divided segments; and a gamut-boundary-setup module which detects the color coordinate value having a greatest radius, which is most adjacent to a center of each segment, according to the divided segments based on the detected color coordinate values having the largest radius among color coordinate values included in the divided segments, and which sets a gamut boundary. The spherical coordinate system is divided based on a hue value and a largest chroma value with respect to each hue.

### CROSS-REFERENCE TO RELATED APPLICATIONS

This application claims priority from Korean Patent Application No. 10-2006-0015716, filed on Feb. 17, 2006, in the Korean Intellectual Property Office, the disclosure of which is incorporated herein by reference in its entirety.

### BACKGROUND OF THE INVENTION

1. Field of the Invention

Methods and apparatuses consistent with the present invention relate to gamut mapping and gamut boundary setup and, more particularly, to setting a gamut boundary based on a spherical coordinate system and a chroma value of a color sample, and for performing gamut mapping using the set gamut boundary.

2. Description of the Related Art

Generally, a color input/output apparatus for reproducing colors, such as a monitor, a scanner, a camera, and a printer, uses different color spaces or color models according to its field of application. For example, in the case of a color image, a printing apparatus uses the cyan, magenta, and yellow (CMY) color space, a color cathode ray tube (CRT) monitor and a computer graphics apparatus uses the red, green, blue (RGB) color space, and apparatuses that must process hue, chroma, and luminance use the hue, saturation, and intensity (HSI) color space. Further, in order to define colors that can be exactly reproduced in any apparatus, i.e., colors independent of apparatuses, a Commission Internationale de l'Eclairage (CIE) color space is also used, which representatively includes the CIEXYZ color space, CIELab color space, CIELuv color space, and others.

In addition to such color spaces, ranges of an expressible color, i.e., gamuts, may be different in different color input/output apparatuses. If the same image is produced by different input/output apparatuses, the image is seen differently due to a difference in the gamut. When gamuts differ, it is necessary to perform gamut mapping for properly converting the currently inputted color signals so that the different gamuts can be matched, thereby improving color reproduction.

FIG. 1 is a diagram illustrating general gamut mapping. In FIG. 1, S1 and S2 represent a gamut of a source device and a gamut of a target device, respectively, and X1 and X2 represent a color of an original image of a source device and a color of an image after mapping, respectively. In the graph illustrated in FIG. 1, an x-axis represents chroma and a y-axis represents lightness.

Referring to FIG. 1, gamut boundaries of the source device and the target device are set; here, the gamut of the source device is wider than that of the target device. When gamut mapping is performed according to the set gamut boundaries, the color of the original image of the source device must be mapped within the gamut of the target device. That is, when a gamut is mapped using the set gamut boundaries, the color X1 of the image of the source device located outside the gamut of the target device is mapped to the color X2 of the gamut boundary of the target device. This is for enabling color reproduction to be accomplished in the target device by mapping the color of the original image of the source device, which is located outside of the target device, within the gamut of the target device. As described above, the gamut boundaries are set, so that the color of the original image of the source device is mapped within the gamut of the target device.

In the meantime, gamut mapping among different color input/output apparatuses is generally performed for lightness and chroma in a state where hue does not change after the color space of input color signals is converted. In detail, the input color signals are converted from a Device Dependent Color Space (DDCS), such as RGB and CMY, to a Device Independent Color Space (DICS), such as CIEXYZ and CIELab, and the DICS is converted to a CIE lightness, chroma, and hue (CIELCH) coordinate system, and then gamut mapping is performed for lightness and chroma on a plane having constant hue, i.e., a lightness versus chroma (LC) plane.

FIG. 2 is a diagram illustrating a method for setting a gamut boundary according to the related art.

Referring to FIG. 2, first, in a CIELab coordinate system, this color coordinate system is optionally and uniformly divided. Further, a gamut boundary is set using the Lab values of a predetermined number of color samples assigned to divided points. However, when Lab values do not exist in divided points, a gamut boundary is set using color coordinate values generated through an interpolation method. In FIG. 2, a value X3 in the divided point corresponds to a color coordinate value generated through the interpolation method using values X4 to X6 adjacent to the divided point.

However, when the gamut boundary is set using the interpolation method, an error may occur due to an interpolation error. Further, a specific unmixed color such as R (Red), G (Green), B (Blue), C (Cyan), M (Magenta), or Y (Yellow) may not be expressed in the gamut boundary set by uniformly dividing the CIELab coordinate system.

Therefore, it is necessary to minimize an error of the gamut boundary which can be expressed by a color input/output apparatus, and thus to improve color reproduction capability among different devices.

### SUMMARY OF THE INVENTION

Exemplary embodiments of the present invention overcome the above disadvantages and other disadvantages not described above. Also, the present invention is not required to overcome the disadvantages described above, and an exemplary embodiment of the present invention may not overcome any of the problems described above.

According to an aspect of the present invention, there is provided an apparatus for performing gamut mapping by setting a gamut boundary based on a spherical coordinate system and a chroma value of a color sample, and a method of setting the gamut boundary.

In accordance with another aspect of the present invention, there is provided a gamut-mapping apparatus including a color coordinate conversion module converting color coordinate values of an inputted color sample to values of a spherical coordinate system, and dividing the spherical coordinate system into a predetermined number of segments; a determining module detecting color coordinate values having a largest radius among color coordinate values included in the divided segments; and a gamut-boundary-setup module detecting the color coordinate value having the largest radius, which is most adjacent to a center of each segment, according to the divided segments based on the detected color coordinate values having the largest radius, and setting a gamut boundary, wherein the spherical coordinate system is divided based on a hue value and a largest chroma value with respect to each hue.

In accordance with yet another aspect of the present invention, there is provided a gamut boundary setup method including converting color coordinate values of an inputted color sample to values of a spherical coordinate system; dividing the spherical coordinate system into a predetermined number of segments based on a hue value and a largest chroma value with respect to each hue; detecting a color coordinate value having a largest radius among color coordinate values included in the divided segments; and detecting the color coordinate value having the largest radius, which is most adjacent to a center of each segment, according to the divided segments based on the detected color coordinate value having the largest radius, and setting a gamut boundary.

### BRIEF DESCRIPTION OF THE DRAWINGS

The above aspects of the present invention will be more apparent by describing exemplary embodiments of the present invention with reference to the attached drawings, in which:

FIG. 1 is a diagram illustrating general gamut mapping;

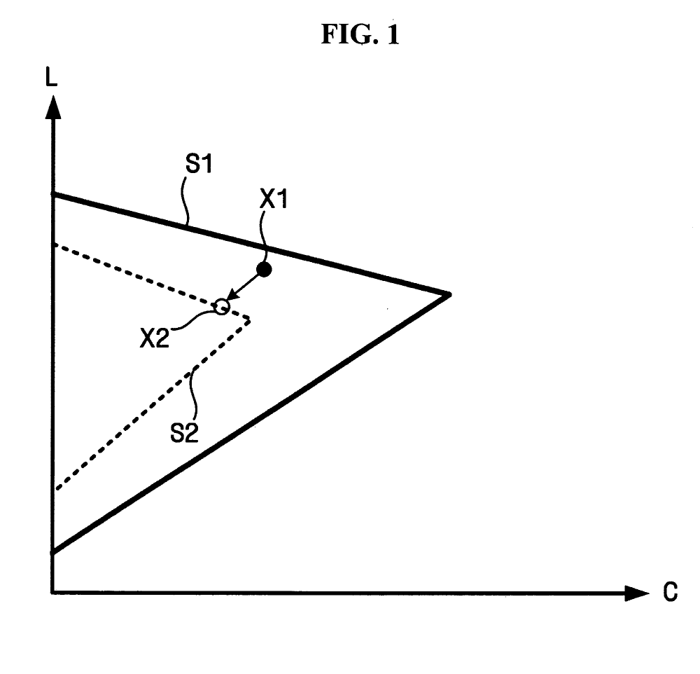

FIG. 2 is a diagram illustrating a method for setting a gamut boundary according to the related art;

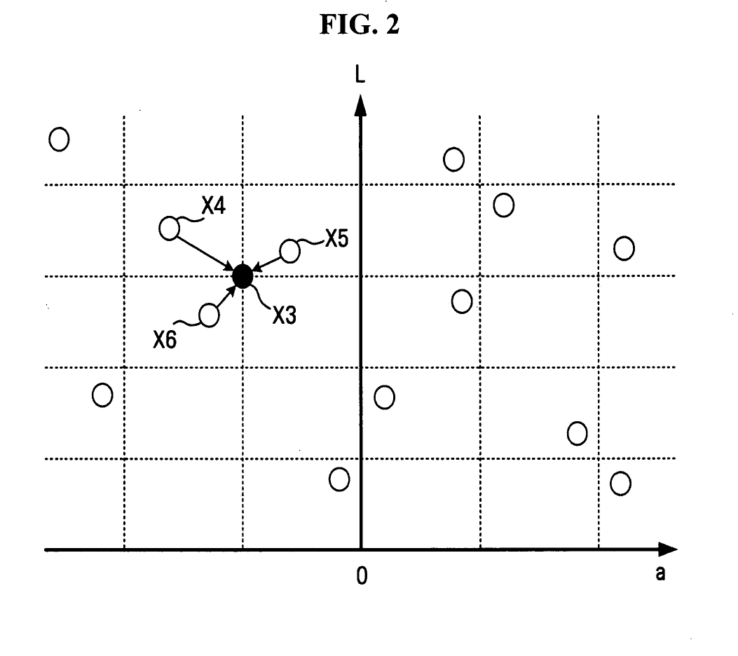

FIG. 3 is a block diagram illustrating the structure of a gamut-mapping apparatus according to an exemplary embodiment of the present invention;

FIG. 4 is a diagram illustrating an example of a reference chart;

FIG. 5 is a diagram illustrating a spherical coordinate system for CIELab color data according to an exemplary embodiment of the present invention;

FIG. 6 is a diagram illustrating the operation of a gamut-boundary-setup module according to an exemplary embodiment of the present invention;

FIG. 7 is a diagram illustrating the operation of a gamut-mapping module according to an exemplary embodiment of the present invention;

FIG. 8 is a flow diagram illustrating a gamut boundary setup process according to an exemplary embodiment of the present invention;

FIG. 9 is a diagram illustrating a CIELab color coordinate system divided based on a predetermined hue angle according to an exemplary embodiment of the present invention;

FIG. 10 is a diagram illustrating segment division according to an exemplary embodiment of the present invention; and

FIG. 11 is a flow diagram illustrating a gamut mapping process according to an exemplary embodiment of the present invention.

### DETAILED DESCRIPTION OF EXEMPLARY EMBODIMENTS

The present invention will be described in detail by explaining exemplary embodiments of the invention with reference to the attached drawings.

The present invention is described hereinafter with reference to flowchart illustrations of user interfaces, methods, and computer program products according to exemplary embodiments of the invention. It will be understood that each block of the flowchart illustrations, and combinations of blocks in the flowchart illustrations, can be implemented by computer program instructions. These computer program instructions can be provided, for example, to a processor of a general purpose computer, special purpose computer, or other programmable data processing apparatus to produce a machine, such that the instructions, which are executed via the processor of the computer or other programmable data processing apparatus, create means for implementing the functions specified in the flowchart block or blocks. These computer program instructions may also be stored, for example, in a computer usable or computer-readable memory that can direct a computer or other programmable data processing apparatus to function in a particular manner, such that the instructions stored in the computer usable or computer-readable memory produce an article of manufacture including instruction means that implement the function specified in the flowchart block or blocks.

The computer program instructions may also be loaded, for example, onto a computer or other programmable data processing apparatus to cause a series of operational steps to be performed on the computer or other programmable apparatus to produce a computer implemented process such that the instructions that execute on the computer or other programmable apparatus provide steps for implementing the functions specified in the flowchart block or blocks.

And each block of the flowchart illustrations may represent a module, segment, or portion of code, which includes one or more executable instructions for implementing the specified logical function(s). It should also be noted that in some alternative implementations, the functions noted in the blocks may occur out of the order. For example, two blocks shown in succession may in fact be executed substantially concurrently or the blocks may sometimes be executed in the reverse order, depending upon the functionality involved.

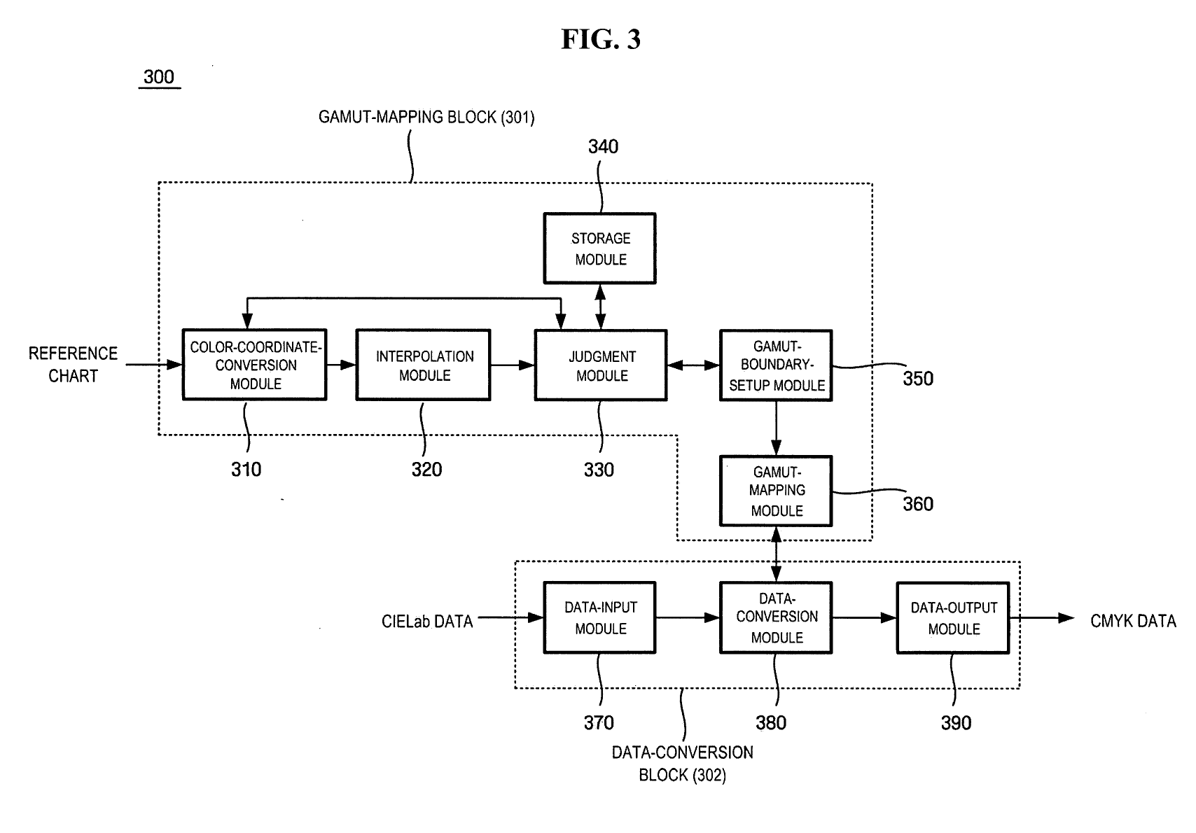

FIG. 3 is a block diagram illustrating the structure of a gamut-mapping apparatus according to an exemplary embodiment of the present invention.

Referring to FIG. 3, the gamut-mapping apparatus 300 according to the present invention may include a gamut-mapping block 301 and a data-conversion block 302.

The gamut-mapping block 301 sets a gamut boundary of a source device and a gamut boundary of a reproduction device based on a reference chart from the reproduction device, thereby generating information for gamut mapping. The data-conversion block 302 converts input data to output data using the generated information for gamut mapping.

When a user uses the reproduction device equipped with the gamut-mapping apparatus 300, it is assumed that input data of the reproduction device correspond to CIELab data and output data of the reproduction device correspond to cyan, magenta, yellow, and black (CMYK) data, for convenience of description about the present invention.

A CIELab model is proposed by the CIE as an international standard for hue measurement. A CIELab is device-independent. That is, a CIELab generates a constant color regardless of a specific device, such as a monitor, a printer, or a computer, which is used for generating and outputting images. A CIELab includes brightness, i.e., lightness element L, and two color tones “a” and “b”. Herein, “a” is disposed between green and red and “b” is disposed between blue and yellow.

A CMYK model is mainly used as input data of a hue output apparatus such as a printer. Theoretically, if cyan, magenta and yellow dyes are mixed, black is obtained. However, since all inks include some impurities, it is difficult to obtain black. Therefore, a separate black ink is mixed. Reproducing a hue by mixing such inks will be referred to as four color printing. Accordingly, when work is performed with an image to be outputted, a CMYK mode must be used.

In the meantime, the process performed by the gamut-mapping block 301 may be mainly executed in the manufacture of the reproduction device.

The gamut-mapping block 301 includes a color-coordinate-conversion module 310, an interpolation module 320, a judgment module 330, a storage module 340, a gamut-boundary-setup module 350, and a gamut-mapping module 360. The data-conversion block 302 includes a data-input module 370, a data-conversion module 380, and a data-output module 390.

The term “module”, as used herein, means, but is not limited to, a software or hardware component, such as a Field Programmable Gate Array (FPGA) or an Application Specific Integrated Circuit (ASIC), which performs certain tasks. A module may advantageously be configured to reside on the addressable storage medium and configured to execute on one or more processors. Thus, a module may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables. The functionality provided for in the components and modules may be combined into fewer components and modules or further separated into additional components and modules.

The color-coordinate-conversion module 310 converts a color coordinate system value of an input color sample, which is measured by a spectrophotometer, to the value of a spherical coordinate system, divides the spherical coordinate system into a predetermined number of segments, and initializes the segments.

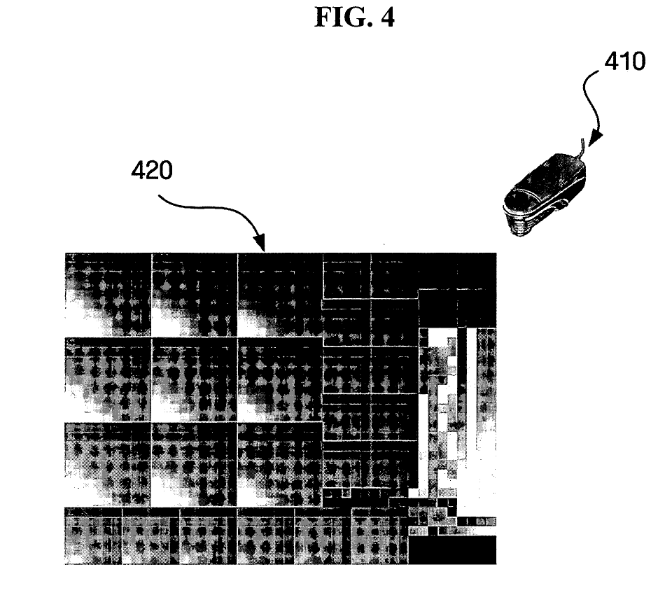

As illustrated in FIG. 4, the color-coordinate-conversion module 310 outputs an input color sample to a printer, generates a reference chart 420, and performs color measurement for the generated reference chart 420 by using a spectrophotometer 410. For example, various charts including an ECI 2002 chart, TC3.5 charts, an IT 8.7/3 chart, etc., have been used as the reference chart 420 in the relevant art.

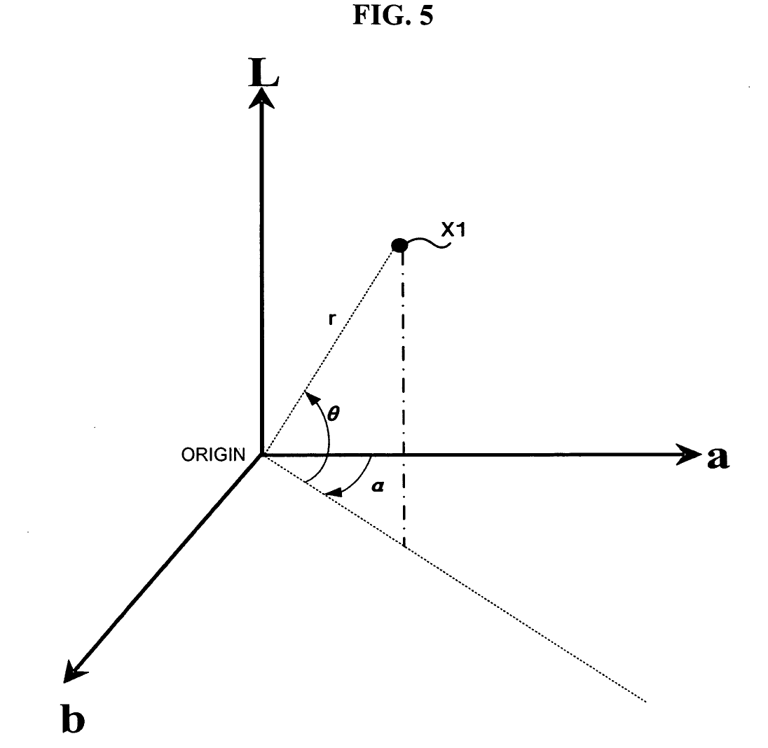

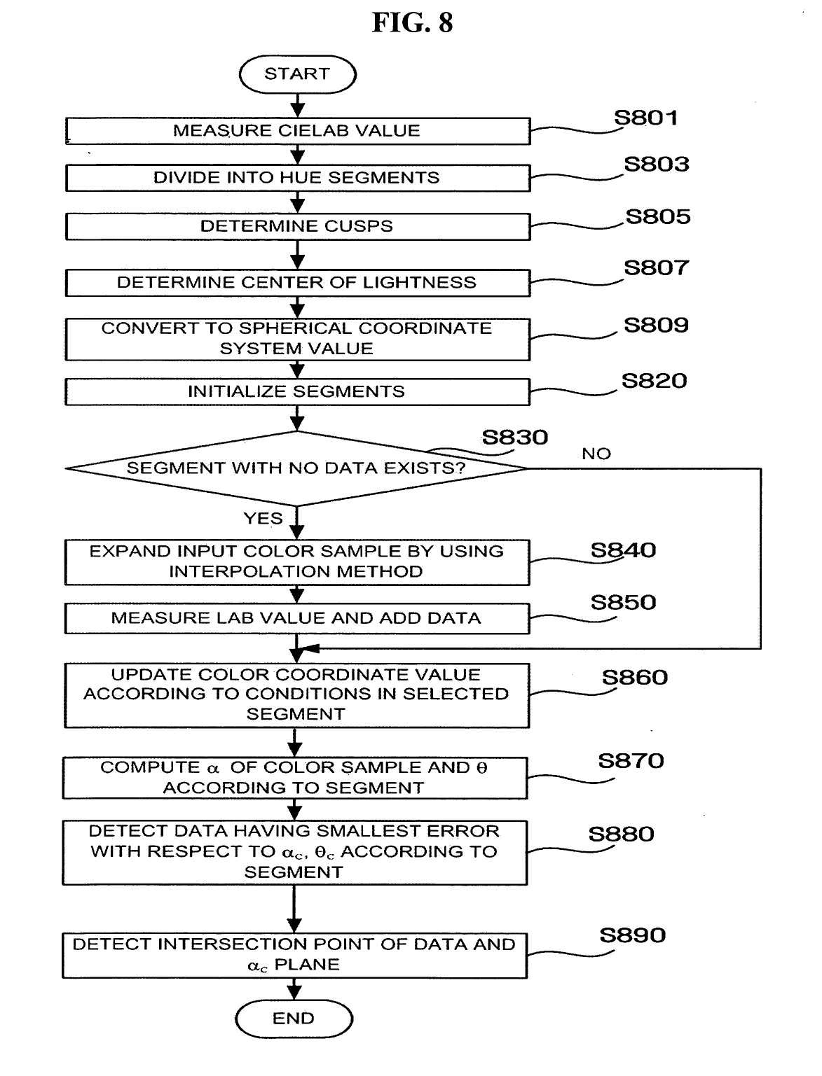

Further, the color-coordinate-conversion module 310 converts the value of the CIELab coordinate system of the measured color sample to the value of the spherical coordinate system using a spherical coordinate system conversion equation as illustrated in FIG. 5. Further, the color-coordinate-conversion module 310 divides a color coordinate value, which is converted to a spherical coordinate system value (r, α, θ), into a predetermined number of segments, and initializes the segments after setting the radius r of the spherical coordinate system value of the divided segments to “0”. Herein, the division into the segments is performed based on the values of α and θ. This division process will be described with reference to FIG. 8.

The interpolation module 320 expands the input color sample using an interpolation method. That is, when a color coordinate value does not exist in the divided segment, the interpolation module 320 performs interpolation for adding a color coordinate value to the segment. In order to detect a gamut boundary, the interpolation module 320 detects a gamut boundary sample from the input color sample. In an area in which the gamut boundary sample cannot be detected from the input color sample, the interpolation module 320 performs interpolation for detecting the gamut boundary sample using adjacent color coordinate system values.

The judgment module 330 compares the value of r, which is stored for each segment, with the value of r′ computed by the spherical coordinate system conversion equation. When r′ is greater than r, the judgment module 330 stores the value of r′ in the storage module 340. Herein, the initial value of r, which is stored for each segment, becomes zero due to segment initialization in the color-coordinate-conversion module 310. In more detail, the judgment module 330 compares a radius, which is stored in the storage module 340 among data existing according to segments, with a radius of the values converted to the spherical coordinate system value. That is, the judgment module 330 selects a specific segment among the segments, which have been divided based on the values of α and θ, from the spherical coordinate system value converted by the color-coordinate-conversion module 310, compares the value of r, which is stored for the selected segment, with the computed value of r′, and stores the greater one of the two values. Accordingly, the judgment module 330 stores a spherical coordinate system value, which has the greatest radius in each segment, in the storage module 340.

The gamut-boundary-setup module 350 converts the gamut of a target device to a CIELCH color coordinate using the color coordinate system values of the gamut boundary detected by the interpolation module 320.

That is, the gamut-boundary-setup module 350 computes the value of α in the detected color coordinate system values of the gamut boundary, and computes θ_{c}, in which θ is the center in each segment including α. Then, the gamut-boundary-setup module 350 detects data having a minimum error from right and left data with respect to α and θ_{c} in each segment. Further, the gamut-boundary-setup module 350 detects the intersection points of the data having a minimum error and the computed α plane. The detected intersection points correspond to gamut boundary values having a constant hue in an LCH color space. That is, the detected intersection points correspond to gamut boundary values on an LC plane.

The gamut-mapping module 360 maps the original images of the source device using a plane, i.e., the α plane, obtained by interconnecting the intersection points detected by the gamut-boundary-setup module 350 in the LCH color space. When the original image of the source device is located outside of the gamut boundary of the reproduction device, the gamut-mapping module 360 maps the original image of the source device to the intersection point of both a straight line, which links the center of the α plane with the original image of the source device, and the gamut boundary of the reproduction device.

The storage module 340 stores a spherical coordinate system value having the greatest radius detected according to the segments by the judgment module 330. In more detail, the storage module 340 stores a value obtained by initializing the segments divided by the color-coordinate-conversion module 310. Further, the radius value stored in the storage module 340 is compared with the radius value computed using the spherical coordinate system conversion equation. As a result of the comparison, the greater radius value is stored in the storage module 340.

The data-input module 370 receives CIELab data. The CIELab data represent hue data provided by the source device.

The data-conversion module 380 converts the received CIELab data to corresponding CMYK data with reference to information about gamut mapping provided by the gamut-mapping module 360.

The data-output module 390 provides the converted CMYK data so that the reproduction device can perform printing work.

In the above description, hue data used by the source data correspond to the CIELab data and hue data used by the reproduction data correspond to the CMYK data. However, the present invention is not limited to these types of hue data. That is, it is possible to use various types of hue data such as CIELab data using a color appearance model, RGB data, luminance, blue-luminance difference, and red-luminance difference (YUV) data, and hue, saturation, and value (HSV) data.

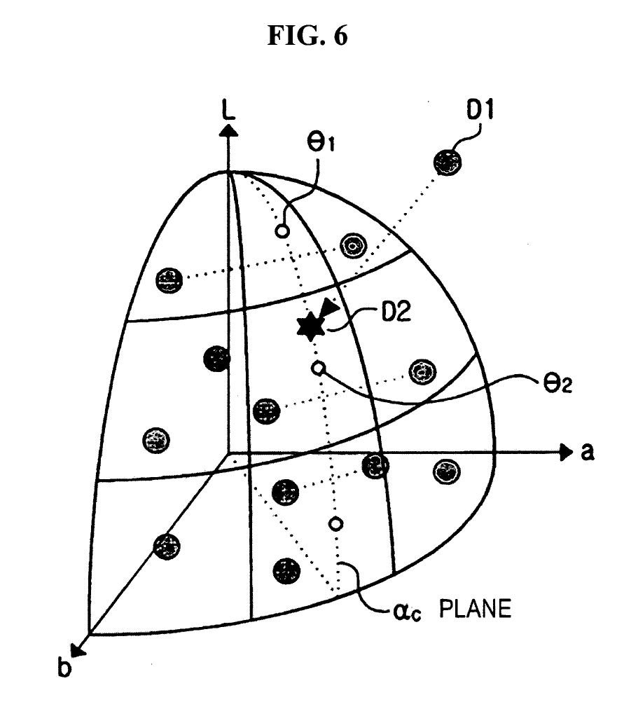

FIG. 6 is a diagram illustrating the operation of the gamut-boundary-setup module according to an exemplary embodiment of the present invention. In FIG. 6, D1 represents the original color of the source device located outside of the gamut of the reproduction device, and D2 represents that D1 is mapped to the gamut boundary of the reproduction device.

Referring to FIG. 6, the gamut-boundary-setup module 350 displays the gamut boundary of the reproduction device, which is detected by the color-coordinate-conversion module 310, the interpolation module 320, and the judgment module 330, on the LC plane of the CIELCH color space.

First, the gamut-boundary-setup module 350 computes the value of α in the detected gamut boundary of the reproduction device. Herein, the computed value of α will be referred to as α_{c}. Further, the gamut-boundary-setup module 350 detects a point in which θ is the center in each segment including α_{c}. Herein, the point in which θ is the center will be referred to as θ_{c}.

The gamut-boundary-setup module 350 detects data having the smallest error between α_{c} and θ_{c} from among right and left data with respect to α_{c} and θ_{c}, according to segments. This is for expressing an exact gamut boundary by detecting the center of a segment and data having a small error when expressing the gamut boundary of the reproduction device on the LC plane.

The gamut-boundary-setup module 350 detects the intersection point of the detected data having the smallest error and an α_{c} plane, and expresses the α_{c} plane on the LC plane of the LCH color space.

In this way, the gamut-boundary-setup module 350 allows the gamut boundary of the reproduction device to be exactly expressed on the LC plane using the color coordinate value of the gamut boundary detected by the color-coordinate-conversion module 310, the interpolation module 320, and the judgment module 330.

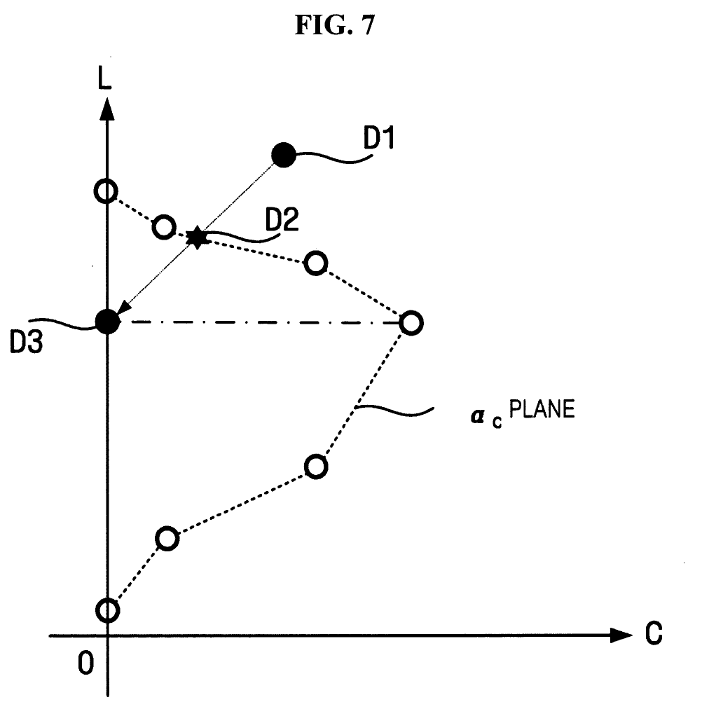

FIG. 7 is a diagram illustrating the operation of the gamut-mapping module according to an exemplary embodiment of the present invention. In FIG. 7, D1 represents the color of the original image of the source device located outside of the gamut of the reproduction device, and D2 represents that D1 is mapped to the gamut boundary of the reproduction device. Further, D3 represents the center of the α_{c} plane on the LC plane. Herein, D3, i.e., the center of the α_{c} plane on the LC plane, corresponds to the value of L for a color sample having the largest chroma.

The gamut-mapping module 360 computes an equation of a straight line which links the color of the original image of the source device with the center of the α_{c} plane in the gamut boundary expressed on the CIELCH color space. Then, the gamut-mapping module 360 maps the color of the original image of the source device to the value of the boundary of the ac plane existing on the straight line using the computed straight line equation. That is, D1, which is the original image of the source device, is mapped to D2 that is the intersection point of both the straight line for linking D1 with the center D3 of the α_{c} plane and the boundary of the α_{c} plane.

FIG. 8 is a flow diagram illustrating a gamut boundary setup method according to an exemplary embodiment of the present invention.

Referring to FIG. 8, a provided color sample is outputted to a printer (reproduction device), and a CIELab value of the outputted color sample is measured by a spectrophotometer (S801). Herein, the hue value and the chroma value of the measured CIELab value are computed using equation (1) below.

$$hue = {tan}^{- 1} ( \frac{b}{a} ) \\ chroma = \sqrt{{a}^{2} + {b}^{2}} \qquad ( 1 )$$

In equation (1), the hue value corresponds to the α illustrated in FIG. 5.

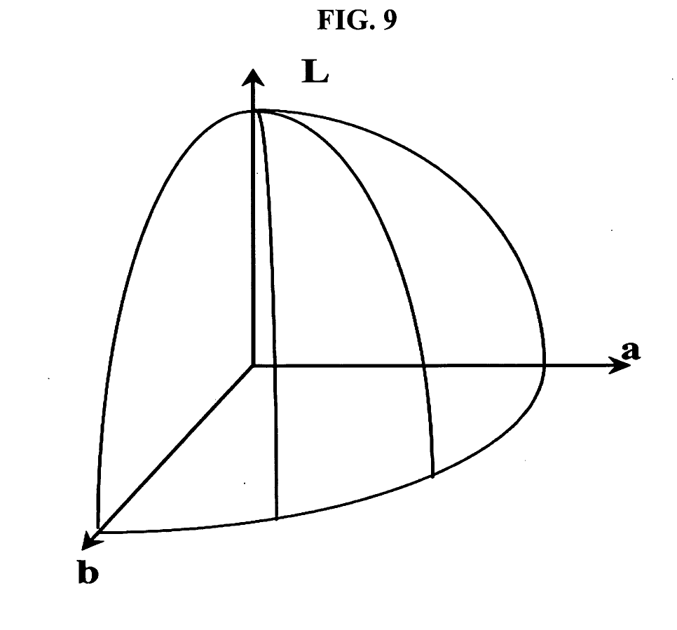

Then, a CIELab color coordinate system is divided into a predetermined number of hue segments based on the hue value computed in equation (1) (S803). FIG. 9 illustrates a CIELab color coordinate system divided according to a predetermined hue angle.

Further, color samples having the largest chroma are selected for each hue segment based on the chroma for all color samples computed in equation (1). Herein, the color samples selected for each hue segment correspond to cusps of corresponding hue segments, respectively (S805).

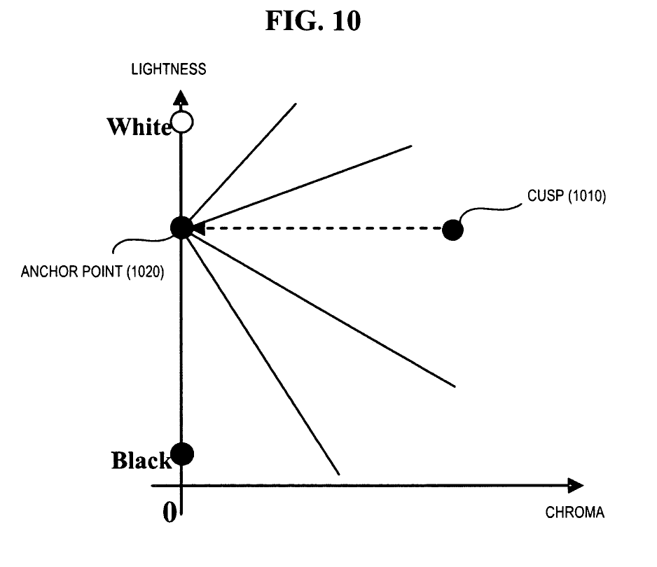

Then, as illustrated in FIG. 10, the coordinate space of lightness-chroma is divided into a predetermined number of segments based on the lightness value of a cusp for each hue segment. In FIG. 10, the lightness value of a cusp 1010 for a corresponding hue segment is indicated as an anchor point 1020, and the anchor point 1020 becomes a center point of lightness in the CIELab coordinate system (S807).

The measured CIELab value is converted to the value of a spherical coordinate system format r, α, and θ (S809). Herein, the Lab value of an input color sample may be converted to a spherical coordinate system value using equation (2) below.

$$r = \sqrt{{( L - {L}_{anchor\_point} )}^{2} + {chroma}^{2} )} \\ θ = {tan}^{- 1} ( \frac{L - {L}_{anchor\_point}}{chroma} ) \\ α = {tan}^{- 1} ( \frac{b}{a} ) \qquad ( 2 )$$

In equation (2), (r, α, and θ) represent values of the spherical coordinate system, and (L, a, and b) represent values of the CIELab coordinate system. Herein, a random reference value in the CIELab coordinate system is (L_{anchor}_{_{—}}ₚₒᵢₙₜ, 0, 0).

Then, the divided segments are initialized (S820). That is, a radius, which is the value of r of the segments of the divided color samples, is set to 0, and the segments are initialized. The values of the spherical coordinate system of the segments initialized as described above are stored in the storage module 340, and S801, S803, S805, S807, and S809 may be performed by the color-coordinate-conversion module 310.

Then, whether a segment with no data exists is determined (S830).

If a segment with no data for a color coordinate value exists, data is generated for this segment using adjacent data through various interpolation methods (S840). Herein, the generated data correspond to a CIELab color coordinate value.

A color sample including a segment with the data generated through the interpolation method is outputted to the printer (reproduction device) again, a Lab value is measured by the spectrophotometer, and the color sample is used as data added to the input color sample according to the results of the measured Lab value (S850).

Then, a specific segment is selected from the divided segments based on the values of α and θ of the color sample converted to the spherical coordinate system format, and the color coordinate value of the segment stored in the storage module 340 is updated according to predetermined conditions in the selected segment (S860). Further, when color coordinate values existing in the selected specific segment are converted to values of the spherical coordinate system format, the value of r of the specific segment stored in the storage module 340 is compared with the value of r′ converted using equation (2) among color coordinate values existing in the specific segment. As a result of the comparison, when the value of r′ is greater than the value of r, the value of r′ is stored in the storage module 340. When different color coordinate values exist in the specific segment, the value of r″ among the color coordinate values converted using equation (2) is compared with the value of r′ stored in the storage module 340. When the value of r″ is greater than the value of r′, the radius of the specific segment is updated to the value of r″, and is stored in the storage module 340. That is, a color coordinate value having the largest radius value among the color coordinate values existing in the specific segment is stored in the storage module 340. This is for storing the largest radius in each segment in the storage module 340 by the judgment module 330, and detecting a color coordinate value approximating a gamut boundary, thereby detecting the gamut boundary.

In step S830, when a segment with no data for a color coordinate value does not exist, the color coordinate value having the largest radius value among the color coordinate values existing in the specific segment is stored in the storage module 340 without performing the interpolation for data addition.

Then, the value of α of the color sample is computed, and a point is selected in which the value of θ is the center in each segment having the computed value of α (S870). Herein, the computed α will be referred to as α_{c}, and the point, in which θ is the center, will be referred to as θ_{c}.

Further, data having the smallest error from right and left data with respect to α_{c} and θ_{c} are detected in each segment having the value of α (S880). This is for expressing the gamut boundary of the target device on the CIELCH color space using the data having the smallest error.

Then, an intersection point of the detected data having the smallest error and the α_{c} plane is detected (S890). In this way, the α_{c} plane is expressed on the LC plane of the CIELCH color space.

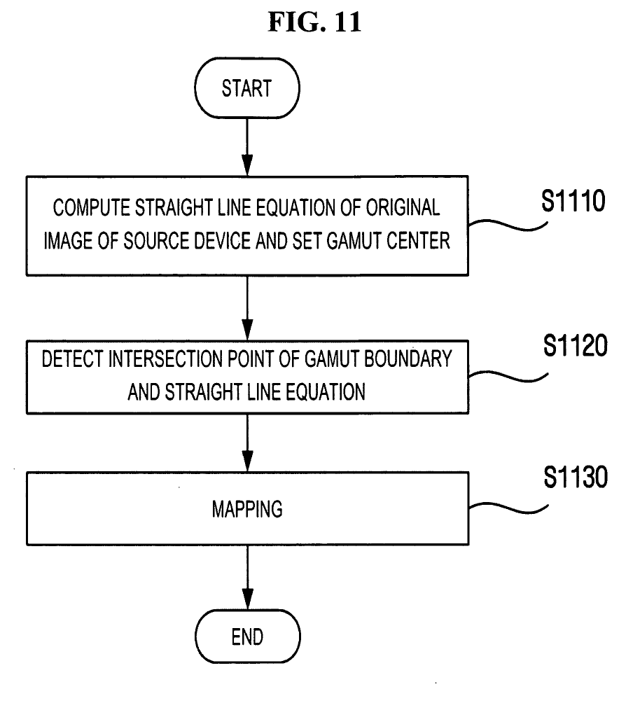

FIG. 11 is a flow diagram illustrating the gamut mapping process according to an exemplary embodiment of the present invention.

Referring to FIG. 11, as described in FIG. 8, it is possible to map the gamut of the source device to the gamut of the reproduction device using the set gamut boundary of the reproduction device. First, an equation of a straight line is computed, which links the center of the set gamut, i.e., the center of the α_{c} plane, with the original image of the source device located outside of the α_{c} plane (S1110). Herein, the center of the α_{c} plane indicates a lightness value corresponding to a color sample having the largest chroma value, and corresponds to the anchor point 1020 as illustrated in FIG. 10.

Then, an intersection point of the boundary of the α_{c} plane and the computed straight line equation is detected (S1120), and the color of the original image of the source device existing outside of the α_{c} plane is mapped to the detected intersection point (S1130). When the color of the original image of the source device exists outside of the α_{c} plane, the color of the original image must be mapped to the gamut of the reproduction device so that the original image of the source device can be reproduced in the reproduction device. The color of the original image of the source device existing outside of the α_{c} plane is mapped to the gamut boundary of the reproduction device in the central direction of the α_{c} plane.

According to the present invention as described above, it is possible to improve the color reproduction capability of different color input/output devices.

Although exemplary embodiments of the present invention have been described for illustrative purposes, those skilled in the art will appreciate that various modifications, additions, and substitutions are possible, without departing from the scope and spirit of the invention as disclosed in the accompanying claims.

What is claimed is:

1. A gamut-mapping apparatus comprising:
a color-coordinate-conversion module which converts color coordinate values of an inputted color sample to values of a spherical coordinate system, and which divides the spherical coordinate system into a predetermined number of segments;
a judgment module which detects the color coordinate values having a largest radius from among the color coordinate values included in the divided segments; and
a gamut-boundary-setup module which detects, for each of the divided segments, the color coordinate value having the largest radius which is most adjacent to a center of the respective divided segment, and which sets a gamut boundary;
wherein the spherical coordinate system is divided based on a hue value and a largest chroma value with respect to each hue.

2. The gamut-mapping apparatus of claim 1, further comprising an interpolation module which adds a color coordinate value using an adjacent color coordinate value when a segment having no color coordinate value exists among the divided segments.

3. The gamut-mapping apparatus of claim 1, further comprising a storage module which stores the color coordinate values according to the divided segments, and which stores the color coordinate values having the largest radius which are detected by the judgment module.

4. The gamut-mapping apparatus of claim 1, wherein the spherical coordinate system is expressed by r, α, and θ computed using:
$$\begin{matrix}r = \sqrt{{( L - {L}_{anchor\_point} )}^{2} + {chroma}^{2} )} \\ θ = {tan}^{- 1} ( \frac{L - {L}_{anchor\_point}}{chroma} ) \\ α = {tan}^{- 1} ( \frac{b}{a} )\end{matrix}$$
wherein L, a, and b represent values in the CIELab coordinate system, respectively, chroma=\sqrt{a²+b²}, and L_{anchor}_{_{—}}ₚₒᵢₙₜ represents a lightness value for a color sample having a largest chroma among color samples belonging to a hue segment for a predetermined α.

5. The gamut-mapping apparatus of claim 1, further comprising a gamut-mapping module which maps a gamut of a source device to a gamut of a reproduction device based on the gamut boundary set by the gamut-boundary-setup module.

6. A gamut boundary setup method comprising:
(a) converting color coordinate values of an inputted color sample to values of a spherical coordinate system;
(b) dividing the spherical coordinate system into a predetermined number of segments based on a hue value and a largest chroma value with respect to each hue;
(c) detecting the color coordinate values having a largest radius from among the color coordinate values included in the divided segments; and
(d) detecting, for each of the divided segments, the color coordinate value having the largest radius which is most adjacent to a center of the respective divided segment, and setting a gamut boundary.

7. The gamut boundary setup method of claim 6, further comprising, after the dividing the spherical coordinate system, adding a color coordinate value using an adjacent color coordinate value when a segment having no color coordinate value exists among the divided segments.

8. The gamut boundary setup method of claim 6, further comprising, after the detecting the color coordinate values having the largest radius, storing the color coordinate values according to the divided segments, and storing the color coordinate values having the largest radius from among the color coordinate values included in the divided segments.

9. The gamut boundary setup method of claim 6, wherein the spherical coordinate system is expressed by r, α, and θ is computed by:
$$\begin{matrix}r = \sqrt{{( L - {L}_{anchor\_point} )}^{2} + {chroma}^{2} )} \\ θ = {tan}^{- 1} ( \frac{L - {L}_{anchor\_point}}{chroma} ) \\ α = {tan}^{- 1} ( \frac{b}{a} )\end{matrix}$$
wherein L, a, and b represent values in the CIELab coordinate system, respectively, chroma=\sqrt{a²+b²}, and L_{anchor}_{_{—}}ₚₒᵢₙₜ represents a lightness value for a color sample having a largest chroma among color samples belonging to a hue segment for a predetermined α.

10. The gamut boundary setup method of claim 6, further comprising mapping a gamut of a source device to a gamut of a reproduction device based on the set gamut boundary.
